(19) United States
(12) Patent Application Publication
(10) Pub. No.: US 2024/0264235 A1
(43) Pub. Date: Aug. 8, 2024

(54) SYSTEMS AND METHODS FOR STATE-OF-CHARGE REMAPPING

(71) Applicant: DEERE & COMPANY, Moline, IL (US)

(72) Inventors: Yiqi Liu, Raleigh, NC (US); Ricardo Schacht Rodriguez, Guadalupe (MX)

(21) Appl. No.: 18/164,825

(22) Filed: Feb. 6, 2023

(51) Int. Cl. G01R 31/367; H02J 7/00

(52) U.S. Cl. CPC G01R 31/367; H02J 7/0048; H02J 7/005

(57) ABSTRACT

A system that accommodates remapping of a state-of-charge of a rechargeable battery for different battery operating voltage ranges without repeating battery characterization testing. A first state-of-charge system can correspond to a characterization state-of-charge that is associated with a characterization operating voltage range. A second state-of-charge system can correspond to the remapped, user-defined state-of-charge that corresponds to a user-defined operating voltage range. The user-defined state-of-charge can be obtained using at least results from characterization testing based on the characterization operating voltage range, and without results from characterization testing based on the user-defined operating voltage range. The characterization state-of-charge can be used at least as an input for the parameter lookup tables utilized at least by an equivalent circuit model, and the user-defined state-of-charge can be used in connection with at least an external interface of the associated product in which the battery is utilized.

### FIELD OF THE DISCLOSURE

The present disclosure generally relates to rechargeable batteries, and, more specifically, to state-of-charge (SOC) remapping for rechargeable batteries to provide parallel state-of-charge systems.

### BACKGROUND

Various types of rechargeable batteries can be utilized in a variety of different types of products. Often internal systems of such products utilize or derive information regarding the status or condition of the rechargeable battery, including information regarding the state-of-charge of the battery. In at least some instances, such information may also be useful to an operator of the product. However, products can be designed such that certain limitations or constraints may be placed on the operation of the battery, including, for example, with respect to the voltage range at which the battery may operate. Such design features can impact the corresponding information sensed, or derived, relating to the operation or condition of the battery. Yet, an operator of the product would typically be unaware of such design features, and the associated impact such design features can have on information regarding the status or condition of the battery. In such situations, battery related information provided to the operator may not meet the operator's expectations, which could possibly result in operator confusion and frustration. Attempts to prevent such operator confusion can involve creating additional lookup tables for the different design features of, or constraints placed on, the battery. Yet, attaining such additional lookup tables often involves undertaking relatively extensive battery testing for the different design features, including testing such design features under different conditions, which can be timely and expensive.

### SUMMARY

The present disclosure may comprise one or more of the following features and combinations thereof.

In one embodiment of the present disclosure, a state-of-charge remapping system can determine a characterization state-of-charge and a user-defined state-of-charge for a rechargeable battery. The state-of-charge remapping system can comprise at least one processor and a memory coupled to the at least one processor. The memory can include instructions that when executed by the at least one processor cause the at least one processor to receive an initial user-defined state-of-charge, the initial user-defined state-of-charge corresponding to a user-defined operating voltage range, the user-defined operating voltage range being within, and a narrower range than, a characterization operating voltage range that corresponds to the characterization state-of-charge. Further, the at least one processor is further configured to convert the initial user-defined state-of-charge to an initial characterization state-of-charge using results of characterization testing obtained for the characterization operating voltage range, and without use of results of characterization testing based on the user-defined operating voltage range. Additionally, the at least one processor is further configured to initialize, using the initial characterization state-of-charge, an equivalent circuit model, and generate, from operation of the equivalent circuit model, at least the updated characterization state-of-charge. The at least one processor can also be configured to convert, using information derived from the results of the characterization testing obtained for the characterization operating voltage range, the updated characterization state-of-charge to the updated user-defined state-of-charge.

In another embodiment, a state-of-charge remapping system can determine a characterization state-of-charge and a user-defined state-of-charge for a rechargeable battery using results of characterization testing obtained for a characterization operating voltage range that corresponds to the characterization state-of-charge. The state-of-charge remapping system can comprise at least one processor and a memory coupled to the at least one processor. The memory can include instructions that when executed by the at least one processor cause the at least one processor to receive a first signal corresponding to a sensed battery voltage, receive a second signal corresponding to a sensed battery load current, and estimate, using the first and second signals, via leveraging, for example, using a reformation of an equivalent circuit model to estimate, using at least the first and second signals, a characterization state-of-charge. Additionally, the at least one processor can convert the characterization state-of-charge to the user-defined state-of-charge using the results of characterization testing obtained for the characterization operating voltage range, and without use of results of characterization testing based on the user-defined state-of-charge.

In a further embodiment of the present disclosure, a method is provided for online reconfiguration of a battery operating voltage range. The method can comprise receiving a signal in response to a change in a state of health condition of a rechargeable battery, the rechargeable battery being operated at a first user-defined operating voltage range, the first user-defined operating voltage range being different than, and within, a characterization operating voltage range of the battery. In response to receiving the signal, adjusting the first user-defined operating voltage range can be adjusted to provide a second user-defined operating voltage range, the second user-defined operating voltage range being different than the first user-defined operating voltage. An initial user-defined state-of-charge can be determined that corresponds to the second user-defined operating voltage range. The method can also include converting the initial user-defined state-of-charge to an initial characterization state-of-charge using characterization testing obtained for a characterization operating voltage range, the characterization operating voltage range being different than the second user-defined operating voltage range. Using the initial characterization state-of-charge, a value can be generated for each of one or more parameters of an equivalent circuit model. The method can also include generating, via operation of the equivalent circuit model, an updated characterization state-of-charge. The updated characterization state-of-charge can be converted to an updated user-defined state-of-charge using results of characterization testing using an operating voltage range that is different than the second user-defined operating voltage range, and without use of results of characterization testing based on the second user-defined state-of-charge.

These and other features of the present disclosure will become more apparent from the following description of the illustrative embodiments.

### BRIEF DESCRIPTION OF THE DRAWINGS

The disclosure described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIG. 1 illustrates an exemplary equivalent circuit model (ECM) for a rechargeable battery.

FIG. 2 illustrates a diagrammatic view of an exemplary system with which aspects of the subject technology can be implemented.

FIG. 3 is a simplified flow diagram of an exemplary method for state-of-charge remapping for rechargeable batteries that provides parallel state-of-charge systems.

FIG. 4 illustrates an exemplary open-circuit voltage (OCV)/state-of-charge (SOC) curve.

FIG. 5 illustrates a block diagram graphically illustrating an exemplary implementation of the method shown in FIG. 3 with a battery plant model simulation.

FIG. 6 illustrates a block diagram graphically illustrating an exemplary model of an implementation of the method shown in FIG. 3 by controller of a battery management system.

FIG. 7 is a simplified flow diagram of an exemplary method for the application of parallel state-of-charge systems with an online reconfiguration of a rechargeable battery operating voltage range.

Corresponding reference numerals are used to indicate corresponding parts throughout the several views.

### DETAILED DESCRIPTION

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

A number of features described below may be illustrated in the drawings in phantom. Depiction of certain features in phantom is intended to convey that those features may be hidden or present in one or more embodiments, while not necessarily present in other embodiments. Additionally, in the one or more embodiments in which those features may be present, illustration of the features in phantom is intended to convey that the features may have location(s) and/or position(s) different from the locations(s) and/or position(s) shown.

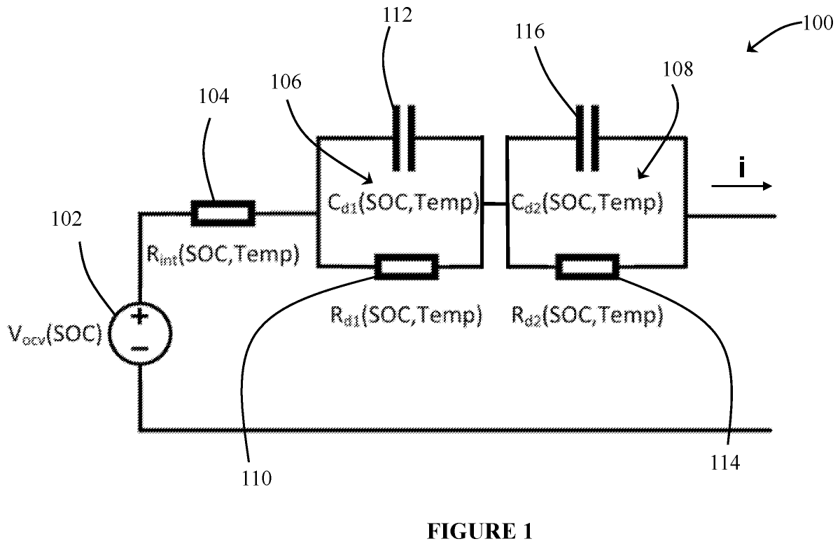

FIG. 1 illustrates an exemplary equivalent circuit model (ECM) 100 for a rechargeable battery, such as, for example, a lithium-ion battery. The illustrated ECM 100, among other ECM configurations, can be configured to simulate and study the relationships between input current/power and output voltage at a variety of different battery, or associated system, operating conditions. Moreover, the ECM 100 can be used to simulate a system in which the battery is incorporated to evaluate whether the battery is, or can, supply sufficient power to the system. The ECM 100 can also simulate the impact, including potential damage, the battery 206 can experience in such a system, including, for example, damage related to either, or both, over-voltage or over-current, among other potential damage to the battery.

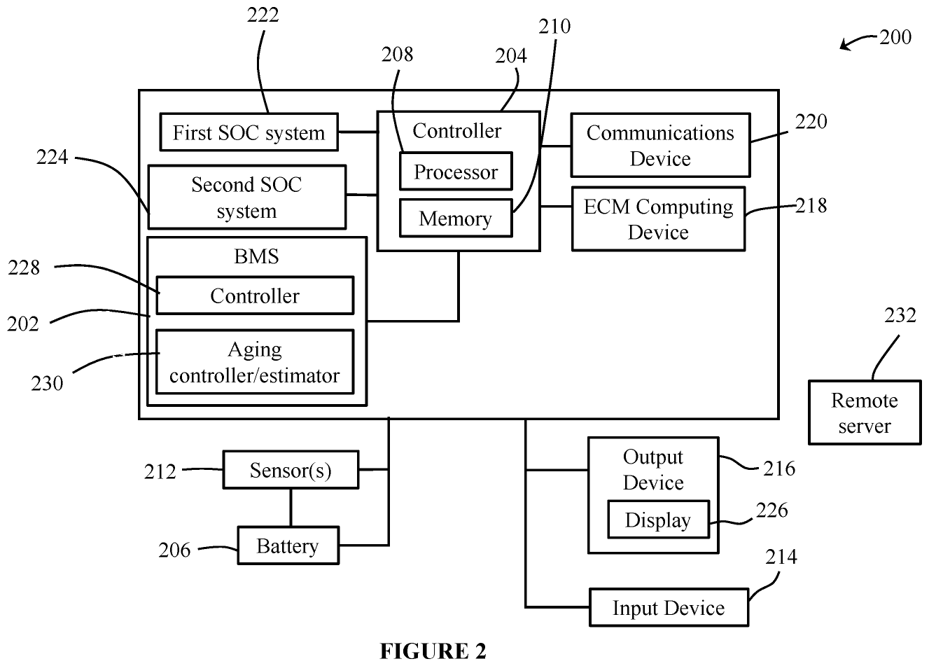

The exemplary ECM 100 shown in FIG. 1, among other ECM configurations, can also be used by a battery management system (BMS) 202, including, for example, by a controller 228 of a BMS 202, as shown for example in FIG. 2. The BMS 202 can utilize the ECM 100 in a variety of different manners, including in connection with decisions made, and information provided, by the BMS 202. For example, in certain applications, the BMS 202, or other components of an associated system, can utilize the ECM 100 in connection with estimating one or more, of a state-of-charge (SOC) estimation, state-of-power (SOP), and state-of-energy (SOE), among other estimations.

The illustrated ECM 100 includes a plurality of electrical components, such as, for example, a voltage source 102 (V_{OCV}), an internal resistor (Rᵢₙₜ) 104, a first resistor-capacitor (RC) pair 106, and a second RC pair 108. As shown, in the exemplary ECM 100, the first RC pair 106 has a first resistor (Rₐ₁) 110 and first capacitor (C_{d1}) 112, and the second RC pair 108 has a second resistor (Rₐ₂) 114 and second capacitor (Cd₂) 116. The ECM 100 can use such electrical components, as well as the indicated arrangement of the electrical components, as shown in FIG. 1, to equivalently mimic battery electrical dynamics without actually modeling all of the complex electrochemical reactions that can occur inside the battery. While FIG. 1 illustrates a particular collection, and the associated arrangement, of electrical components, the number, types, and arrangement of components of the ECM 100 can vary for different ECMs, including, for example, with respect to ECMs that model either, or both, different types or capacities of batteries, among other characteristics and features of the particular battery for which the ECM 100 is modelling.

Each of the electrical components of the ECM 100 can be modeled as lookup tables as functions of state-of-charge (SOC) and temperature (TEMP). Additionally, arguments, such as, for example, current (i), can be added to the lookup tables or functions. With such an approach, the accuracy of the state-of-charge (SOC) directly affects the accuracy of the ECM 100, including, for example, the resistance and capacitance values used by the ECM 100 and the resulting voltage and current relationship, and estimated, or updated, state-of-charge (SOC) outputted by the ECM 100. With the ECM 100, state-of-charge (SOC) can, for example, be applied as:

$$SOC = {SOC}_{0} - \frac{\int i \cdot dt}{C} \qquad ( 1 )$$

wherein SOC₀ is the initial state-of-charge, current (i) is defined to be positive for discharging as a function of time (dt), and C′ is battery capacity.

A characterized battery capacity (C′) can be used in Equation (1) to calculate state-of-charge (SOC) with a given initial state-of-charge (SOC₀), current, and time. During such battery characterization tests, the electrical components of the ECM 100 can each be characterized at different state-of-charge (SOC) levels. However, such battery characterization tests are specific to particular types of conditions, or specific parameters. Thus, a relatively large number of characterization tests are often performed to account for changes in parameters and conditions. Thus, such characterization tests can be time-consuming, and can take, for example, weeks or months to finish. For example, with respect to the illustrated ECM 100, such battery characterization tests can involve characterizing, at different state-of-charge (SOC) levels, each of the voltage source 102 (V_{OCV}), internal resistor (Rᵢₙₜ) 104, first resistor (R_{d1}) 110, first capacitor (C_{d1}) 112, second resistor (R_{d2}) 114, and second capacitor (C_{d2}) 116. The results from the battery characterization tests can be tabulated for use in lookup tables (LUT), including lookup tables for each of the above-identified components, among others.

State-of-charge (SOC) is typically defined as corresponding to a certain battery capacity that is characterized between two voltage levels, namely an end-of-charge voltage (EOCV) and an end-of-discharge voltage (EODV), at a specified current pattern. For example, state-of-charge (SOC) can be defined as corresponding to a battery capacity that is characterized or measured by discharging the battery from a characterized voltage level of 4.2 volts (V) to a characterized voltage level of 2.5 V using a 1 amp (A) constant discharging current. In at least certain applications, the characterized voltage levels utilized for the characterized operating voltage range in state-of-charge (SOC) determinations are at or around the full operating voltage range of the battery. Such characterized operating voltage ranges can correspond to how a battery that is properly sized, and, moreover, that is not oversized, is anticipated to actually be utilized in the associated application. Moreover, in at least certain situations, such characterization testing can relate to the overall unlimited operating capacities of the battery.

In at least certain applications, the operating voltage range at which a battery will actually operate can be different from the characterization operating voltage range. For example, an objective in terms of product design and manufacturing can be to attain a degree of modularity across several different products or models. Such modularity can, for example, utilize the same style, model, or type (collectively “model”) of battery with different types of products and product models. By designing different products to utilize the same model of battery, benefits can be realized with respect to the commonality in the design and manufacturing of the associated interfaces and software, as well as with respect to the associated testing of the battery and the corresponding product. However, power requirements can vary for different products. Thus, a consequence of such a modular approach can be the battery model can, at least in terms of battery capacity, be properly sized for some products and the associated applications, and be, at least to an extent, oversized for other products and applications.

For example, a battery in some applications can have a battery capacity, such as, for example, in terms of kilowatts per hour (kWh), that is around, if not slightly above, the power requirements of a first product line. In such a situation, the battery capacity of the battery can generally be similar, or correspond, to the power requirements of the products of the first product line. However, with respect another, second product line that utilizes the same model of battery as the first product line, such a battery capacity can exceed the power requirements of the products of the second product line. Thus, unlike the products of the first product line in which nearly all of the battery capacity can be utilized, the products of the second product line may require, as one non-limiting example, only about 85% of the battery capacity, among other percentages of battery capacity.

Further, a battery can age more significantly when operated at high operating voltages and at very low operating voltages. Thus, while the battery in the above example can be oversized for use with the second product line, the lower power requirements of the products of the second product line can be utilized to at least attempt to extend the life of the battery, including relative to the anticipated battery life of the use of the same model of battery with the first product line. In such a scenario, one approach to extending battery life for the second product line is to limit the battery operating voltage range in terms of the EOCV and the EODV.

Altering a battery operating voltage range could create operator confusion at least with respect to information provided to the operator regarding the capacity of the battery. For example, the state-of-charge (SOC) span of a battery is often communicated to operators in terms of a percentage, which can, for example, be numerically and graphically represented to the user. With such representations, the upper and lower ranges of the state-of-charge (SOC) are often depicted in manner that can indicate 100% state-of-charge (SOC) (e.g., full charge), and 0% state-of-charge (SOC) (e.g. no charge). Thus, using the above-discussed example of a battery utilized with a product of the first product line, and wherein the EOCV is not limited, the battery may be able to attain about a 100% state-of-charge (SOC). Accordingly, in this example, when the state-of-charge (SOC) of a fully charged battery is displayed numerically or graphically to the operator of a product of the first product line, the state-of-charge (SOC) may indicate a complete, or nearly complete, 100% charge. However, with respect to the products of the second product line, in at least an effort to extend the life of the battery, the second product line can be configured to limit the EOCV of the battery to, for example, about 85% state-of-charge (SOC), among other percentages of state-of-charge (SOC). Thus, for purposes of the second product line, charging the battery to, or about, 85%, can constitute a full charge. Yet, in such situations, the BMS 202 or other components of the product may prevent the battery from being charged beyond 85%. However, in such a situation, the operator may be unaware of such a design feature. Thus, when the unknowing operator is presented with information indicating the state-of-charge is not exceeding 85%, even after relatively long charging periods, the operator may become confused or concerned as to the condition or performance of the battery or the associated product of the second product line.

Limiting the EODV of the operating voltage range also can at least create similar operator confusion. Again, with respect to the above-discussed example, as the voltage operating range of the first product is not limited, the batteries utilized with the products of the first product line can be allowed to drop to an EODV at which a 0% state-of-charge is generally attained. Thus, in the event a product of the first product line ceases operation, a 0% state-of-charge can provide an operator an indication of the reason for the stoppage in operation. Moreover, in such a situation the information provided to the operator could indicate the resolution to the stoppage in operation is to recharge the battery. However, again, in an attempt to extend the life of the battery, the BMS 202 or other component of the second product line can prevent the EODV of associated batteries used with the products of the second product line from reaching generally low levels. Thus, continuing with the prior example, the products of the second product line can be configured such that the EODV for the batteries used with the second product line are limited to not going below a voltage that corresponds, for example, to 35% state-of-charge (SOC), among other state-of-charge (SOC) percentages. Thus, in such a scenario, when a battery of a product of the second product line drops to a state-of-charge (SOC) of about 35%, operation of the associated product may stop to avoid violating, or falling below, the EODV limit. However, if an operator were unaware of such a design feature, the operator may be confused as to why the product does not operate when the information provided to the operator indicates that the battery still has about 35% state-of-charge. Moreover, the operator may be unaware that in such a situation that although the battery still has a state-of-charge, because the product has been designed to limit EODV to 35%, the battery is in need of charging. Such confusion can also cause the operator to misdiagnose the reason as to why the associated product has ceased operation, which can further lead to operator confusion and frustration.

Additionally, traditionally, creating limited voltage operating ranges using new EOCVs and EODVs can result in undertaking additional characterization tests that are directed to the new limited voltage operating ranges. Thus, such characterization testing can be conducted in addition to the characterization testing that was conducted for the non-limited voltage operating ranges that were discussed above. However, as previously discussed, characterization tests can be timely. Such time can further be exacerbated by analyzing different EOCVs and EODVs in connection with different products, models of batteries, and temperatures, among other variable and operating conditions.

According to embodiments of the subject application, remapping of a state-of-charge (SOC) of a battery, without additional characterization testing, can allow a first, characterization state-of-charge system 222 (FIG. 2) to operate in parallel with a second, user-defined state-of-charge system 224 (FIG. 2). Additionally, for example, the subject disclosure facilitates at least testing or simulating usage of a battery at a variety of different operating voltage ranges for various applications without repeating battery characterization testing. According to certain embodiments, the first state-of-charge system 222 can correspond to a characterization state-of-charge (SOC_{c}), which is the state-of-charge associated with a characterization operating voltage range, while the second state-of-charge system 224 can correspond to the remapped, user-defined state-of-charge (SOCᵤ), which is the state-of-charge that corresponds to a user-defined operating voltage range. According to such embodiments, the characterization state-of-charge (SOC_{c}) can be used at least as the input for the parameter lookup tables utilized at least by the ECM 100, and the user-defined state-of-charge (SOCᵤ) can be used in connection with at least an external interface of the associated product in which the battery is utilized, such as, for example, a display 226, among other output devices 216.

FIG. 2 is a diagrammatic view of an exemplary system 200 with which aspects of the subject disclosure can be implemented. The system 200 can comprise, or be part of, an online system or, alternatively, an offline system. With respect to online systems, the illustrated system 200 can be part of a particular device or product having a battery 206, including, but not limited to, at least partially, if not fully, electrically powered vehicles, products, tools, and devices. For example, according to certain embodiments, the system 200 can be part of an electric or hybrid mower, utility vehicle, automobile, or agricultural vehicle, among other types of vehicles. Additionally, the system 200 can be incorporated into electric or hybrid yard, agricultural, or construction tools, vehicles, and devices, including, but not limited to, zero-turn mowers, stand-on mowers, walk-behind mowers, front and/or wide area mowers, utility vehicles, compact tractors, utility tractors, specialty tractors, large tractors, row crop tractors, combine harvesters, excavators, dump trucks, backhoes, crawler loaders, dozer, motor graders, wheel loaders, tractor loaders, backhoes, or sprayers, among others. With respect to offline systems, according to other embodiments, the system 200 can be a design, testing, simulation, or measuring system or unit that may or may not be incorporated into another device or product.

As seen in FIG. 2, the system 200 can include a controller 204 that has a memory 210 having instructions stored therein that are executable by a processor 208 to cause the processor 208 to receive input, such as, for example, from at least one or more of a battery management system (BMS) 202, battery sensor 212, and an input device 214, and an output a signal to at least an output device 216. The processor 208 can be embodied as, or otherwise include, any type of processor, controller, or other compute circuit capable of performing various tasks such as compute functions and/or controlling the functions of the system 200. For example, the processor 208 can be embodied as a single or multi-core processor(s), a microcontroller, or other processor or processing/controlling circuit. In some embodiments, the processor 208 can be embodied as, include, or otherwise be coupled to an FPGA, an application specific integrated circuit (ASIC), reconfigurable hardware or hardware circuitry, or other specialized hardware to facilitate performance of the functions described herein. Additionally, in some embodiments, the processor 208 can be embodied as, or otherwise include, a high-power processor, an accelerator co-processor, or a storage controller. In some embodiments still, the processor 208 can include more than one processor, controller, or compute circuit.

The memory 210 can be embodied as any type of volatile (e.g., dynamic random access memory (DRAM), etc.) or non-volatile memory capable of storing data therein. Volatile memory may be embodied as a storage medium that requires power to maintain the state of data stored by the medium. Non-limiting examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular embodiments, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4 (these standards are available at www.jedec.org). Such standards (and similar standards) may be referred to as DDR-based standards and communication interfaces of the storage devices that implement such standards may be referred to as DDR-based interfaces.

In some embodiments, the memory 210 can be embodied as a block addressable memory, such as those based on NAND or NOR technologies. The memory 210 can also include future generation nonvolatile devices, such as a three dimensional crosspoint memory device (e.g., Intel 3D XPoint™ memory), or other byte addressable write-in-place nonvolatile memory devices. In some embodiments, the memory 210 can be embodied as, or may otherwise include, chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory 210 can refer to the die itself and/or to a packaged memory product. In some embodiments, 3D crosspoint memory (e.g., Intel 3D XPoint™ memory) can comprise a transistor-less stackable cross point architecture in which memory cells sit at the intersection of word lines and bit lines and are individually addressable and in which bit storage is based on a change in bulk resistance.

The system can also include a battery 206. A variety of different types of batteries can be used as the battery 206, including rechargeable and non-rechargeable batteries. For example, according to certain embodiments, the battery 206 can be a lithium-ion battery. However, other types of batteries can be utilized as the battery 206, including, but not limited to, alkaline, carbon zinc, silver oxide, zinc air, nickel cadmium (NiCd), and nickel-metal hydride (NiMH), among others, can be utilized. As seen in FIG. 2, according to certain embodiments, the battery 206 can be electrically coupled to the controller 204, or, alternatively, be part of the controller 204. Further, according to at least certain embodiments, the battery 206 can electrically power at least the controller 204, among other portions of the system 200.

An ECM computing device 218 can include the ECM 100, and can be embodied as hardware, firmware, software, virtualized hardware, emulated architecture, and/or a combination thereof, and is configured to simulate battery voltage-current dynamics. Moreover, the ECM computing device 218 can be utilized to provide characterization state-of-charge (SOC_{c}) values for the first state-of-charge system 222, which, as discussed above, can correspond to the characterization operating voltage range. According to certain embodiments, the ECM computing device 218 can include lookup tables or functions of SOC_{c} and temperature (TEMP), among other arguments, that are utilized as, or as part of, the ECM 100. While the ECM computing device 218 is illustrated in FIG. 2 as being separate from other portions of the system 200, according to other embodiments the ECM computing device 218, or ECM 100, can be implemented in, or as a part of, the controller 204 or the BMS 202, including, for example, implemented in a microcontroller of the controller 204 or the BMS 202.

According to at least online embodiments, the system 200 can include the BMS 202, which can be embodied as hardware, firmware, software, virtualized hardware, emulated architecture, and/or a combination thereof. Further, the BMS 202 can be configured to either, or both, control or monitor the operation and condition of the battery 206. For example, according to certain embodiments, the BMS 202 can at least periodically or continuously either, or both, monitor or estimate the state-of-charge of the battery 206, among other characteristics or conditions that can relate to, or impact, the management, health, and performance of the battery 206. According to certain embodiments, the ECM 100 can use information obtained, and/or calculated, by the BMS 202 or controller 204, or otherwise inputted into the system 200 via the input device 214, in connection with determining either or both the characterization state-of-charge (SOC_{c}) and the user-defined state-of-charge (SOCᵤ).

According to certain embodiments, operation of the BMS 202 can be aided by information provided by one or more battery sensors 212 that can be electrically coupled to the battery 206. Such sensor(s) 212 can be configured to provide a variety of information regarding the status, condition, and/or operation of the battery 206, including, for example, information regarding the current outputted by the battery 206, voltage measured in the system 200 that utilizes electrical power from the battery 206, the temperature of the battery 206, or the ambient temperature around the battery 206, as well as various combinations thereof. Additionally, at least some information obtained by the battery sensor(s) 212 can be utilized in connection with the operation of the ECM 100, including with respect to determining, including estimating, the actual state of charge of the battery 206.

The system 200 can further include a communications device 220 that can communicate information from the system 200 to other devices and databases. The communications device 220 can be embodied as hardware, firmware, software, virtualized hardware, emulated architecture, and/or a combination thereof. According to certain embodiments, the communications device 220 can comprise a transceiver that is configured to wirelessly communicate information, as well as receive information, that may pertain to, or assist, the system 200, including the ECM 100, in determining either or both the characterized operating voltage range, user-defined operating voltage range, characterization state-of-charge (SOC_{c}), and the user-defined state-of-charge (SOCᵤ).

The system 200 can also include an input device 214, including, but not limited to, an operator input device 214, such as, for example, a keyboard, touch screen, mouse, and/or scanning device, among other input devices. The input device 214 can allow an operator to input information or data into the system 200 that can be utilized by the controller 204, ECM computing device 218, or include the ECM 100, as well as combinations thereof. For example, with respect to offline embodiments, the input device 214 can be utilized to identify either or both of the characterize and user-defined operating voltage ranges, including, for example, the associated EOCV and the EODV for the voltage operating ranges. Thus, the input device 214 can be utilized, for example, to identify the limited EOCV and the limited EODV in at least instances in which the full capacity of the battery 206 is not to be utilized. The input device 214 can also be utilized to input variables associated with the ECM 100. Thus, with respect to above Equation (1) and the ECM 100 shown in FIG. 1, the input device 214 can be utilized to input one or more, if not all, of an initial state-of-charge (SOC₀), temperature, or current, as well as combinations thereof, among other parameters of the ECM 100.

The system 200 can further include one or more output devices 216, such as, for example, a display 226, that can provide visual information to the operator, including, for example, the current state-of charge (SOCᵤ) of the battery 206 for the user-defined operating voltage range, as can outputted by the second state-of-charge system 224. The display 226 can also include other information obtained by the BMS 202, including information that is actually sensed or measured, or that is derived using actual measurements, that can be utilized for at least purposes of displaying the characterization state-of-charge (SOC_{c}), or the user-defined state-of-charge (SOCᵤ), as well as combinations thereof, among other information. According to certain embodiments, including online systems, the display 226 may provide information indicating the current or present level of the state-of-charge of the battery 206 in terms of the user-defined state-of-charge (SOCᵤ), rather than in terms of the characterization state-of-charge (SOC_{c}), so as to minimize or limit the above-discussed issues regarding potential operator confusion.

The first and second state-of-charge systems 222, 224 can, for example, be embodied as hardware, firmware, software, virtualized hardware, emulated architecture, and/or a combination thereof. Further, while the first and second state-of-charge systems 222, 224 are illustrated in FIG. 2 as being separate from other portions of the system 200, according to other embodiments the first and second state-of-charge systems 222, 224 can be implemented in, or as a part of, the processor 208, controller 204 or the BMS 202, including, for example, implemented in a microcontroller of the controller 204 or the BMS 202. Additionally, according to certain embodiments, the below-operations of the first and second state-of-charge systems 222, 224 discussed herein can be performed by the processor 208 executing instructions that are stored on the memory 210.

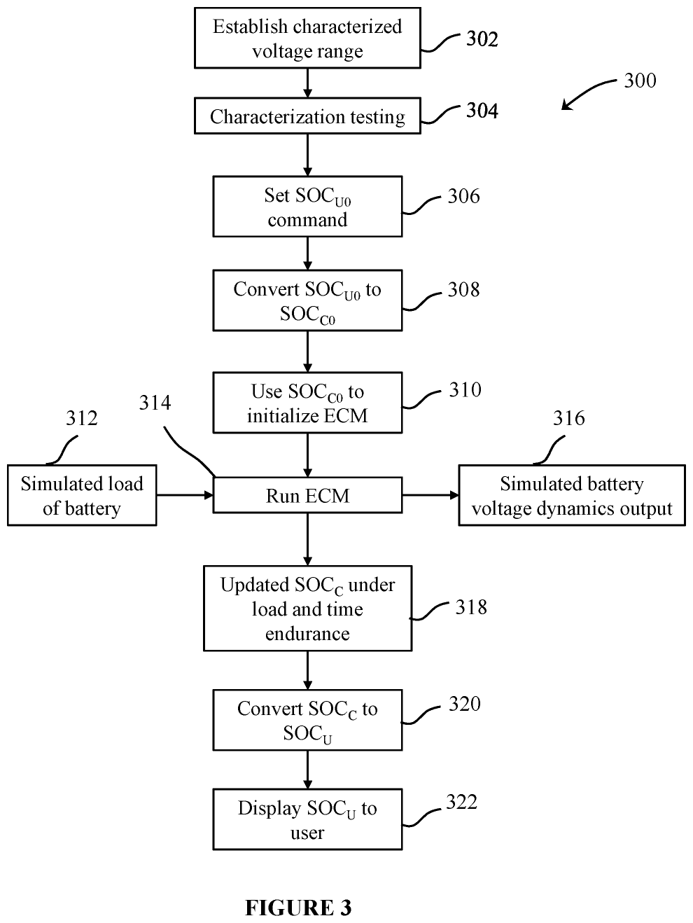

FIG. 3 is a simplified flow diagram of an exemplary method 300 for state-of-charge remapping for rechargeable batteries 206 to provide parallel state-of-charge systems 222, 224. The method 300 is described in the context of being carried out by the illustrated exemplary system 200. However, it should be appreciated that method 300 may likewise be carried out by any of the other described implementations, as well as variations thereof, including, for example, as part of a model in connection with simulations by offline embodiments, including, but not limited to, a simulation of a battery plant model.

At block 302, a characterized operating voltage range for the battery 206 can be determined, which can provide the upper and lower limits for the corresponding characterization state-of-charge (SOC_{c}). As mentioned above, in at least certain situations, the characterized operating voltage range can be at or around the full operating voltage range of the battery 206. Additionally, or alternatively, the characterized operating voltage range for the battery 206 can be determined based on the performance ability of the battery 206, which can, for example, be based on the chemistry of the battery 206. Additionally, in some cases, such as, for example, in which the battery 206 is not over or undersized for the particular application, the characterized operating voltage range can be the range of the application in which the battery 206 is being utilized for that application. Thus, for example, referencing the above-discussed example in which a battery 206 is properly sized for the products of the first product line, the characterized operating voltage range may correspond to the operating voltage range requirements of the first product line. Further, in at least certain situations, the characterized operating voltage range can extend between the end-of-charge voltage (EOCV), which can correspond to 100% SOC_{c}, and the end-of-discharge voltage (EODV), which can correspond to 0% SOC_{c}, at a specified current pattern. Thus, in one non-limiting example, the initial characterized voltage operating range can be established as a range between 4.2 V (100% SOC_{c}) and 2.5 V (0% SOC_{c}).

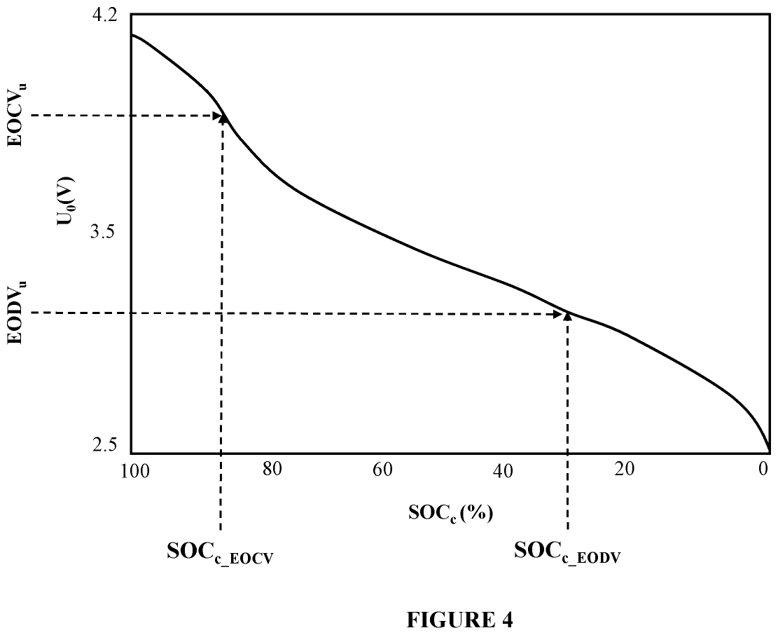

At block 304, to the extent not already performed, mapping can be performed relating to the battery 206, and moreover, relating to the characterized voltage operating range and the corresponding SOC_{c}. As previously discussed, such mapping can be obtained through battery characterization tests, and can be modeled as lookup tables (LUT), which may provide information as a function of the characterization state-of-charge (SOC_{c}) and temperature (TEMP). For example, FIG. 4 illustrates a non-limiting example of such mapping in the form of an open-circuit voltage (OCV)/state-of-charge (SOC) curve. In the illustrated example, the y-axis corresponds to a range of the characterized open-circuit voltage (OCV), which in this example generally extends between the characterized operating voltage range, and the x-axis corresponds to the associated percentage (%) of the characterization state-of-charge (SOC_{c}). As seen, in FIG. 4, in this example, 100% of the characterization state-of-charge (SOC_{c}) generally corresponds to the upper limit of the characterized operating voltage range (EOCV), which is 4.2 V, and 0% of the characterization state-of-charge (SOC_{c}) generally corresponds to the lower limit of the characterized operating voltage range (EODV), which in this example is 2.5 V.

At block 306, a user-defined operating voltage range can be established or set, including, for example, be a predetermined user-defined operating voltage range. For example, as previously discussed, the user-defined operating voltage range can be set to meet the particular needs of a product or device in which the battery 206, or model of the battery 206, is or will be incorporated in a manner that may minimize operation of the battery 206 at generally high or low operating voltages, which may thereby extend the life of the battery 206. For example, referring to the prior example, while the battery 206 may be properly sized for the first product line, the same battery or battery model may be oversized for the second product line. Thus, as the power requirements of the second product line may less than the first product line, the user-defined operating voltage range associated with use of the battery 206 with the second product line can be within, and narrower, than the characterized operating voltage range. For example, continuing with prior example in which the characterized operating range of the battery 206 may be between 4.2 V (EOCV_{c}) and 2.5 V (EODV_{c}), the user-defined operating voltage range can be set at 4 V (EOCVᵤ) and 3.3 V (EOCVᵤ). In such an example, the EOCVᵤ can correspond to a user-defined state-of-charge (SOCᵤ) of 100% SOCᵤ, and the EODVᵤ can correspond to a user-defined state-of-charge (SOCᵤ) of 0% SOCᵤ.

As the user-identified operating voltage range can be a new, or different operating voltage range, characterization tests again could be performed to develop associated characterization information, including parameter lookup tables for use with the ECM 100. However, as mentioned above, given at least the number of different conditions and variations in parameter values, such characterization tests are timely, and thus costly. Further, use of the battery or battery model with different devices or products that have different power and/or energy requirements can, traditionally, require separate or different characterization tests.

Accordingly, the subject disclosure provides systems and methods for utilizing the results of a set of the characterization tests for battery 206 that are based on particular voltage operating range (e.g., the characterized voltage operating range) with other, different voltage operating ranges. Thus, subject disclosure provides ways to utilize previously developed characterization information, including ECM parameter lookup tables, with different operating voltage ranges without having to perform additional characterization tests for those different operating voltage ranges, and in manner that can provide accurate results, including with respect to associated state-of-charge values.

Accordingly, at block 308, the initial user-defined state-of-charge (SOCᵤ₀), which can be provided by the user, can be converted to an initial characterization state-of-charge (SOC_{c0}) value, which can correspond to the initial state-of-charge (SOC₀) in above-identified Equation (1). For example, using the illustrated exemplary curve shown in FIG. 4, the location of the upper limit of the user-defined operating voltage range, which in FIG. 4 can correspond to the “EOCVᵥ”, can be located along the y-axis, which can again correspond to a characterized open-circuit voltage. From the depicted curve, using the “EOCVᵤ”, the corresponding characterization state-of-charge (SOC_{c}), as identified as a percentage of a full characterization state-of-charge (SOC_{c}), can be identified, as indicated by “SOC_{c_HOCV}” in FIG. 4. Thus, in discussed example, as the upper limit of the initial user-defined operating voltage range has been set or predefined at as being an EOCV of 4 V, the corresponding characterization state-of-charge (SOC_{c}), as a percentage, is about 85% SOC_{c}. A similar approach can be utilized with respect to lower limit of the user-defined operating voltage range (represented in FIG. 4 as “EODVᵤ”) to identify the corresponding characterization state-of-charge (SOC_{c}), as a percentage, as indicated in FIG. 4 by “SOC_{c_EODV}”. Accordingly, in the example discussed above in which the lower level, or EODVᵤ, of the initial user-defined operating voltage range is 3.3 V, from FIG. 4 the SOC_{c_EODV} is about 35% SOC_{c}.

By identifying the characterization state-of-charge with respect to both the upper and lower limits (EOCV, EODV) of the user-defined operating voltage range, namely SOC_{c_HOCV} and SOC_{c_EODV}, respectively, and knowing that the SOCᵤ for each the upper and lower limits of the user-defined operating voltage range correspond to 100% SOC_{u_EOCV} and 0% SOC_{u_EODV}, respectively, a relationship can be determined between the characterization state-of-charge (SOC_{c}) and the user-defined state-of-charge (SOCᵤ). For example, as the state-of-charge represented by above Equation (1) is a linear function, the relationship between the characterization state-of-charge (SOC_{c}) and the user-defined state-of-charge (SOCᵤ) can be linearly mapped. Such mapping can accommodate the system 200 utilizing a first state-of-charge system 222 and a second state-of-charge system 224, as indicated by FIG. 2, in parallel with each other, as discussed below.

As discussed above, the first state-of-charge system 222 can correspond to the characterization state-of-charge (SOC_{c}). According to such an embodiment, the first state-of-charge system 222 can determine the characterization state-of-charge (SOC_{c}), including the characterization state-of-charge (SOC_{c}) that corresponds to a particular, or selected, user-defined state-of-charge (SOCᵤ). For example, at block 306, an operator can directly initialize a user-defined state-of-charge (e.g. SOCᵤ₀). The first state-of-charge system 222 can utilize the user-initialized SOCᵤ₀ to determine the corresponding initialized characterization state-of-charge (e.g. SOC_{c0}) that corresponds to the initialized user-defined state-of-charge (e.g. SOCᵤ₀). For example, as the relationship between the user-defined state-of-charge (SOCᵤ) and the characterization state-of-charge (SOC_{c}) can be linearly mapped, as discussed above, the initialized characterization state-of-charge (SOC_{c0}) for any given user initialize user-defined state-of-charge (SOCᵤ₀) can be determined, or mapped, by use of the following expression:

$${SOC}_{c} = {SOC}_{u} * ( \frac{{SOC}_{{c}_{EOCV}} - {SOC}_{{c}_{EODV}}}{{SOC}_{{u}_{EOCV}} - {SOC}_{{u}_{EODV}}} ) + {SOC}_{{c}_{EODV}} \qquad ( 2 )$$

While the above example, as well as other examples discussed herein, utilize analytical equations to map or bridge the relationship between the characterization state-of-charge (SOC_{c}) and the user-defined state-of-charge (SOCᵤ), the relationship can be mapped or bridged in variety of different manners, including, but not limited to, lookup tables, empirical equations, direct mapping, among others.

With respect to initialization, the user-defined state-of-charge (SOCᵤ) in Equation (2) is the initialized user-defined state-of-charge (SOCᵤ₀), and the characterization state-of-charge (SOC_{c}) is the initialized characterization state-of-charge (SOC_{c0}). Also, as discussed above, the SOC_{c_EOCV} and SOC_{c_EODV} can be determined via use of existing mapping that may have already been obtained through prior battery characterization tests. Accordingly, with respect to the particular example discussed above with respect to FIG. 4, and in view of Equation (2), for a given initialized user-defined state-of-charge (SOCᵤ₀), the first state-of-charge system 222 can derive the corresponding initialized characterization state-of-charge (SOC_{c0}) via, for example, by the following:

$${SOC}_{c 0} = {SOC}_{u 0} * ( \frac{85 \% - 35 \%}{100 \% - 0 \%} ) + 35 \%$$

At block 310, the determined initial characterization state-of-charge (SOC_{c0}) can be used to determine the corresponding updated, characterization state-of-charge (SOC_{c}). More specifically, the determined initial characterization state-of-charge (SOC_{c0}) can be applied, for example, to Equation (1) as the value for the initial state-of-charge (SOC₀), such as, for example, at a time (t) that equals 0, so as to determine the corresponding, updated characterization state-of-charge (SOC_{c}) based on a given current (i) input and the time endurance, as may be provided via the profile of the simulated load of the battery at block 312. While battery current provided to the ECM 100 via block 312 in the current example is a simulated current, the simulated battery current can generally correspond, or be very close, to the actual current provided by the battery 206.

Block 310 can thus include using at least the initial characterization state-of-charge (SOC_{c0}) in connection with determining at least initial values for parameters of the ECM 100. As seen in FIG. 1, according to the illustrated example, such parameters can include values for the initial resistor 104, the first and second capacitors 112, 116 and the first and second resistors 110, 114. Further, as previously discussed, the electrical components of the ECM 100 can be modeled as lookup tables as functions of state-of-charge (SOC) and temperature (TEMP).

At block 314, the ECM 100 can utilize the initial SOC determined at block 310, and the associated parameter values, in connection with running the ECM 100, or other battery model, to provide a battery voltage dynamics output, as indicated by block 316. The outputted battery voltage dynamics can provide information at least indicating, or used to determine, whether, the inputted current from block 312, as well as based on the dynamics of the battery, as modeled by the ECM 100, be resulting in the battery experiencing, or not experiencing, an under-voltage condition or an over-voltage condition. Moreover, the outputted battery voltage dynamics can provide information as to whether the current level provided by the battery 206 is, or is not, to be adjusted, among other information.

In addition to outputting voltage information at block 316, the ECM 100 can also output an updated characterized state-of charge (SOC_{c}) at block 318. For example, as indicated by Equation (1), over time, as the battery 206 supplies current, the state-of charge (SOC_{c}) can change, which can result in a change in the values of the parameters utilized by the ECM 100, which, again are at least partially as functions of the state-of charge (SOC_{c}). Such changes, including the change in current, can also result in a change in the voltage outputted at block 316. Thus, in connection with covering a period of time, as the ECM 100 is run at block 314, the value of the characterized state-of charge (SOC_{c}), as well as the associated values of the parameters for the ECM 100 that are, at least in part, a function of the characterized state-of charge (SOC_{c}), can continue to be updated at block 318.

Accordingly, the updated characterized state-of charge (SOC_{c}) provided at block 318 can reflect the characterization state-of-charge (SOC_{c}) under the load and time endurance conditions at which the battery 206 may experience, or, alternatively, has experienced. The updated characterized state-of charge (SOC_{c}) can be utilized by the first state-of-charge system 222, such as, for example, providing characterized state-of charge (SOC_{c}) information that can be utilized by the controller 204, BMS 202, processor 208, or other portions of the system 200.

Further, as indicated by block 320, the updated characterization state-of-charge (SOC_{c}) from block 318 can be utilized by the second state-of-charge system 224 to derive a current user-defined state-of-charge (e.g. SOCᵤ). For example, as previously discussed, a linear relationship can exist between SOC_{c} and SOCᵤ. Thus, according to certain embodiments, the second state-of-charge system 224 can be used to convert, or map, the SOC to an SOCᵤ value via an analytical, such as, for example, via:

$${SOC}_{u} = ( {SOC}_{c} - {SOC}_{{c}_{EODV}} ) * \frac{{SOC}_{u \_ E OCV} - {SOC}_{u\_EODV}}{{SOC}_{c\_EOCV} - {SOC}_{c\_EODV}} \qquad ( 3 )$$

with the value for SOC_{c} being provided, for example, by the updated characterization state-of-charge (SOC_{c}) from block 318. As previously mentioned, while the foregoing example utilizes an analytical expression to convert the characterization state-of-charge (SOC_{c}) to the corresponding user-defined state-of-charge (SOCᵤ), such a conversion can be obtained in a variety of other manners, including, for example, via lookup tables, empirical equations, direct mapping, among others. Applying Equation (3) to the above-discussed examples, determination of the user-defined state-of-charge (SOCᵤ) corresponding to a given or updated characterization state-of-charge (SOC_{c}) can be determined via the following:

$${SOC}_{u} = ( {SOC}_{c} - 35 \% ) * \frac{100 \% - 0 \%}{85 \% - 35 \%}$$

The second state-of-charge system 224, among other components of the system 200, can generate a signal such that the user-defined state-of-charge (SOCᵤ) obtained at block 320 can be communicated to an operator at block 322, such as, for example, displayed on the display 226. For example, the user-defined state-of-charge (SOCᵤ) outputted can be in a form that is scaled to the user-defined voltage range. in the example discussed above, if the upper limit (e.g. EOCVᵤ) of the user-defined operating voltage range corresponds to 85% of the characterization state-of-charge (e.g. SOC_{c}), then in instances at which the battery 206 is at the EOCVᵤ, rather than displaying the 85% SOC_{c}, the second state-of-charge system 224 would output for display the corresponding user-defined state-of-charge (e.g. SOCᵤ), which in this example would be 100% SOCᵤ. Similarly, if the battery 206 reaches the lower limit of the user-defined operating voltage range (EODVᵤ), rather than displaying the corresponding characterization state-of-charge (SOC_{c}), which in the above example is 35% SOC_{c}, the second state-of-charge system 224 would output a user state-of-charge (e.g., SOCᵤ) of 0%.

At block 322, the user-identified state-of-charge (SOCᵤ) can be displayed or otherwise communicated to the operator. For example, the controller 204, second state-of-charge system 224, among other components of the system 200, including the processor 208 or the BMS 202, can generate a signal that facilitates the current level of the user-identified state-of-charge (SOCᵤ) being displayed on the display 226, including, for example, as a graphical or numerical representation, or both, among other manners or representations to communicate the current level of the user-identified state-of-charge (SOCᵤ) to the operator.

While the foregoing examples are generally discussed in terms of the state-of-charge (SOC) of the battery 206 being at the opposing ends of the user-defined voltage operating range (EOCVᵤ, EODVᵤ), such as, for example, after completely charging or fully depleting the battery 206, the above-discussed method 300 is also applicable to when the state-of-charge (SOC) of the battery 206 is at a level that is between the corresponding EOCV and EODV levels, or otherwise between 100% SOC and 0% SOC. Thus, for example, during use, when the state-of-charge of the battery 206 corresponds to a characterization state-of-charge (SOC_{c}) that is somewhere between 100% SOC_{c} and 0% SOC_{c}, the above method 300 can be utilized such that the second state-of-charge system 224 can determine the user-identified state-of-charge (SOCᵤ) that corresponds to the current level of the characterization state-of-charge (SOC_{c}).

The above-discussed method 300 can be utilized in a variety of different manners. For example, as discussed above, the first state-of-charge system 222 can, in connection with the ECM 100, utilize the characterized state-of-charge (SOC_{c}) for actual battery dynamic simulation, and can, for example, provide such information to the processor 208, controller 204, or BMS 202, among other components of the system 200. In parallel with the operation of the first state-of-charge system 222, and the associated use by the ECM 100 and controller 204 of the characterized state-of-charge (SOC_{c}), the second state-of-charge system 224 can utilize the characterized state-of-charge (SOC_{c}) being determined or outputted by the first state-of-charge system 222 to determine the corresponding user-defined state-of-charge (SOCᵤ), as well as output that determined user-defined state-of-charge (SOCᵤ) to an external interface, including, but not limited to, a display 226. Thus, in at least certain situations, the operation of the ECM 100 can generally be independent of user-defined operating voltage range selection, as the ECM 100 can, regardless of the user selected operating range, be able to provide information, including provide an updated characterized state-of-charge (SOC_{c}) useable by either or both the first or second state-of-charge systems 222, 224 based on the existing characterized operating range information, including lookup tables.

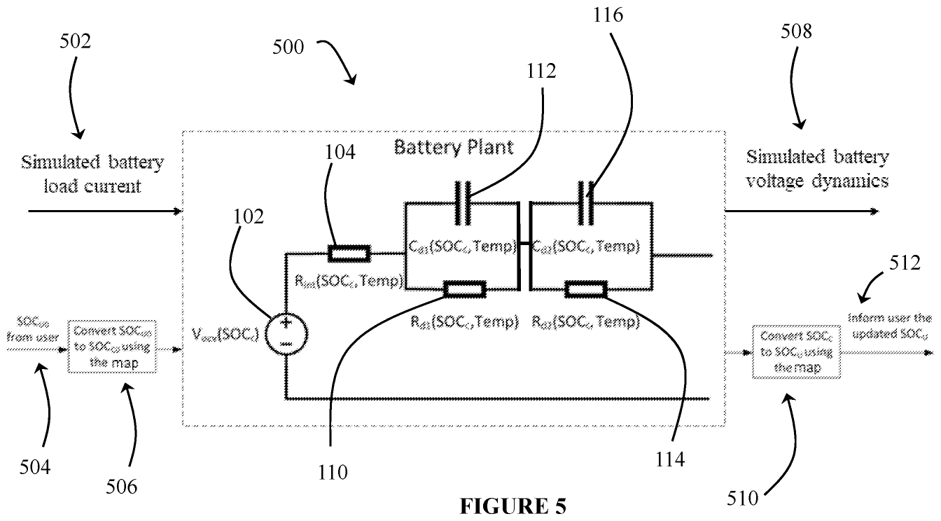

FIG. 5 illustrates a block diagram that graphically illustrates an exemplary implementation of the method 300 shown in FIG. 3 with a battery plant model 500 simulation. According to such an embodiment, the model 500 can include selection 502, for example, by an operator of the simulation, of a current, as indicated in FIG. 5 by “Simulated battery load current”. The selection 502 of the current can be based, for example, on a select amount of current that is to be delivered to an electronic system, including, for example, a system of an electrically powered device, that utilizes, at least in part, electrical power that is provided by the battery 206. Additionally, an initial user-defined state-of-charge (SOCᵤ₀) can be selected 504, such as, for example, by the operator of the simulation. Similar to at least block 308 discussed above with respect to FIG. 3, a conversion 506 can occur in which the initial user-defined state-of-charge (SOCᵤ₀) is converted or mapped to an initial characterized state-of-charge (SOC_{c0}) via at least a portion of method 300 discussed above, including via the approach discussed above with respect to block 308. Again, such a conversion allows for mapping the initial user-defined state-of-charge (SOCᵤ₀) to the initial characterized state-of-charge (SOC_{c0}) using the characterizations previously identified for the characterized operating voltage range, and without having to perform additional characterization testing for the user-defined voltage operating range.

The ECM 100 shown in FIG. 5 can then utilize the initial characterized state-of-charge (SOC_{c0}) to at least initially identify values associated with other parameters of the ECM 100, which, as discussed above, can be obtained, for example, via lookup tables associated with characterization testing of the battery 206 at its characterized operating voltage range and as a function, at least in part, of the initial characterized state-of-charge (SOC_{c}). Thus, in the illustrated example, such lookup tables can be utilized to determine at least initial parameter values for the initial resistor (Rᵢₙₜ) 104 and the first and second resistor-capacitor pair 106, 108, including the associated first and second capacitors (C_{d1}, C_{d2}) 112, 116 and the first and second resistors (R_{d1}, R_{d2}) 110, 114.

As seen in FIG. 5, an output 508 of the model 500 can be simulated battery voltage dynamics, which can include an output of a simulated voltage, or information that can be utilized to determine the simulated voltage. A controller 204, such as, for example, a feedback controller, can then determine whether the determined simulated voltage indicates, or does not indicate, an overvoltage or under-voltage condition of the battery 206 or the associated electronic system. If needed, the feedback controller can also determine an adjustment for the inputted current to at least attempt to avoid such an overvoltage or under-voltage condition.

The output 508 provided by the simulated battery voltage dynamics can also produce information that indicates, or is used to determine, an updated characterization state-of-charge (SOC_{c}) of the battery. As also seen in FIG. 5, similar to blocks 318, 320 discussed above with respect to FIG. 3, the updated characterization state-of-charge (SOC_{c}) outputted 508 by the model 500 can be converted 510, such as, for example, by the second state-of-charge system 224, to a user-defined state-of-charge (SOCᵤ) and communicated 512 to the operator, as well as utilized in continuation of the running of the ECM 100, including, with respect to updating the values of the parameters of the ECM 100.

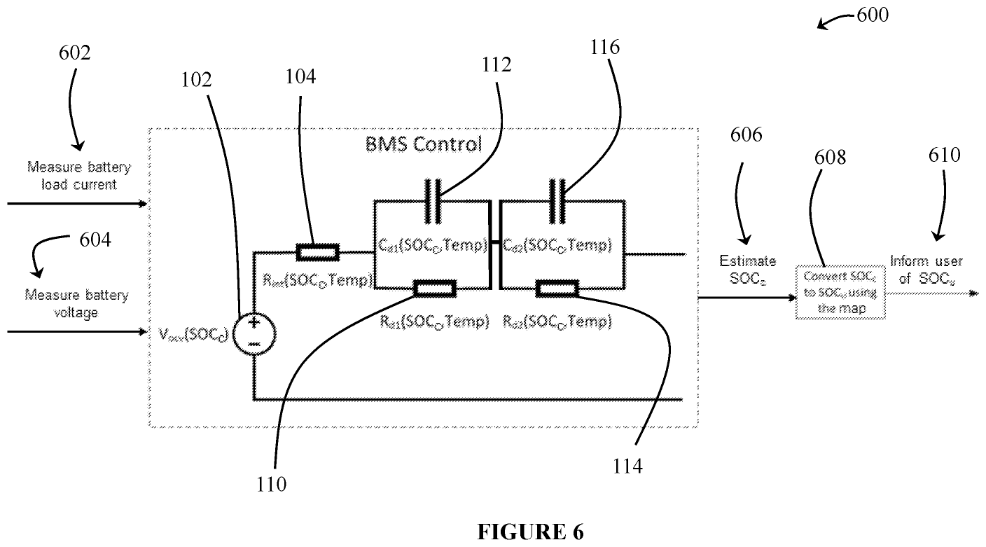

FIG. 6 illustrates a block diagram graphically illustrating a model 600 for an exemplary implementation of the method 300 shown in FIG. 3 by controller 228 (FIG. 2) of a battery management system (BMS) 202 or controller 204 of an associated system 200. The model 600 shown in FIG. 6 can utilize, as inputs 602, 604, a measured or sensed battery load current and a battery voltage, respectively. According to such a model, the measured current and measured voltage can be used to estimate the characterized state-of-charge (SOC_{c}).

As indicated by FIG. 6, the output 606, which leverages the ECM 100, including, for example, via use of a reformation of the ECM 100, can be the current estimated characterization state-of-charge (SOC_{c}). As also seen in FIG. 6, similar to blocks 318, 320 discussed above with respect to FIG. 3, the estimated characterization state-of-charge (SOC_{c}) can be converted 608, such as, for example, via the second state-of-charge system 224, to a user-defined state-of-charge (SOCᵤ) and communicated 610 to the operator.

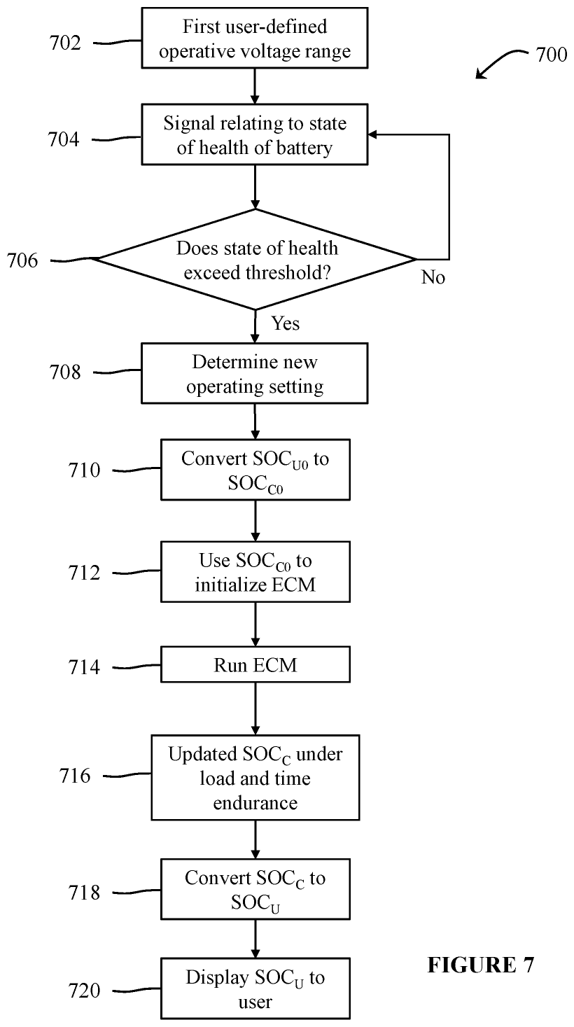

FIG. 7 is a simplified flow diagram of an exemplary method 700 for the application of parallel state-of-charge systems, such as the above-discussed first and second state-of-charge systems 222, 224, in connection with an online reconfiguration of an operating voltage range for a rechargeable battery that is incorporated into a product.

At block 702, a first user-identified voltage operating range can be determined. Similar to the example discussed above with respect to at least FIG. 3, the first user-identified voltage operating range can be within, and narrower than, the corresponding characterized voltage operating range. According to certain embodiments, the first user-identified voltage operating range may, at least temporarily correspond to a factory setting for the first user-identified voltage operating range. Additionally, according to other embodiments, the first user-identified voltage operating range can be a previously adjusted voltage operating range that was selected or implement based on a prior use or outcome of the method 700 discussed herein.

At block 704, a signal can be received regarding, or in response, to a detection of a state of health condition of the battery 206, including, for example, as detected by an aging controller or estimator 230 (FIG. 2) of the BMS 202. For example, the received signal can be triggered in response to a detected change in the state of health condition of the battery 206 that can correspond to a negative condition, or potentially negative condition of, or pertaining to, the battery 206 and/or a condition or state in which the battery 206 is being operated and/or exposed. Thus, such a condition can be attributed to a variety of factors, or combination of factors. For example, the manner in which the battery 206 ages can be attributed to a setting(s) of the battery 206 or device in which the battery 206 is incorporated. Additionally, or alternatively, manner in which the battery 206 ages can also arise as a consequence of the manner in which the battery 206 or associated device are being, or have been, used. Such aging of the battery 206 can be determined in a variety of manners, including, for example, via use of an aging model or algorithm of the aging estimator 230.

In response to the detected health condition, at block 706 a decision can be made as to whether to adjust one or more operation settings of the battery 206. If the operation setting(s) is/are not to be adjusted, the method can resume with monitoring the health condition of the battery 206. The decision of whether to adjust an operation setting of the battery 206 can be based on a variety of criteria, including, for example, whether the detected health condition deviates from a preset value or range by a predetermined threshold. According to certain embodiments, the determination of whether the operation setting is to be adjusted, which can also include, at block 708, the extent or degree of the adjustment can be made online, such as, for example, by the aging estimator 230, BMS 202, processor 208, or controller 228 of the BMS 202 of the device or product in which the battery 206 is located. Additionally, the determination of whether the operation setting is to be adjusted, which can also include the extent or degree of the adjustment can be made remotely. Further, according to certain embodiments, the communications device 220 can communicate information relating to the state of health condition of the battery 206 to a remote location, such as, for example, a remote server 232 (FIG. 2). The remote server 232 can be configured to evaluate the received health condition of the battery 206 to determine if, and the extent, a change is to be made in the operation setting(s). If a change is to be implemented, the remote server 232 can then transmit a signal that is received by the communication device 220 of the system 200 that facilitates a change in the operation setting of the battery 206. Additionally, or alternatively, making an adjustment in the operation setting of the battery 206 may not be in direct response to received health condition information from a particular product, but instead can be communicated to the product as part of a software update.

In response to battery aging, or the manner in which the battery is aging, as detected or estimated by the aging estimator 230, the aging estimator 203, BMS 202, controller 204, or remote server 232 can determine one or more adjusted upper, lower, or both the upper and lower voltage operating range(s) for the battery 206. Such adjustments can also include other control objectives in addition to, or in lieu of, battery aging, including, but not limited to, selected power output for the battery 206 or the associated device in which the battery 206 is located. For example, such a decision can include lowering or raising one or both the EOCV and the EODV of the first user-identified operating voltage range, thereby providing at block 708 a second, adjusted user-identified operating voltage range for the battery 206. Additionally, according to certain embodiments, the second, adjusted user-identified operating voltage range can be automatically determined by the aging estimator 230 or the BMS 202, and automatically implemented, such as, for example, via the BMS 202. Alternatively, according to other embodiments, the aging estimator 230 or the BMS 202, or both, can derive a plurality of different operating voltage range options from which the user can select one to use as the second, adjusted user-identified operating voltage range. Additionally, or alternatively, the user can be prompted to provide or enter, such as, for example, manually, a second, adjusted user-identified operating voltage range for the battery 206. Such a prompting to the user may further include at least a suggested EOCV limit and/or a suggested EODV limit, which may, for example, be determined by the aging estimator 230 or the BMS 202.

At block 710 the first state-of-charge system 222 can utilize the second user-identified voltage operating range to identify the corresponding characterization state-of-charge (SOC_{c}), as discussed, for example, with respect to at least blocks 306, 308 of FIG. 3. Accordingly, as with other embodiments discussed herein, the second user-identified voltage operating range can be remapped by the first state-of-charge system 222 so that the prior characterization testing and associated look-up tables can be reutilized. Thus, as discussed above, the change to, and selection of, the second user-identified operating voltage range may not necessitate incurring the expense, and associated time, that would be associated with running additional characterization tests based on the second user-identified operating voltage range.

Accordingly, the characterization state-of-charge (SOC_{c}) obtained by the first state-of-charge system 222 can be utilized in connection with running the ECM 100 at block 714 in a manner similar to at least that discussed above with respect to at least blocks 310, 314, 318 of FIG. 3, so that an updated characterization state-of-charge (SOC_{c}) can be determined, as indicated by block 716. Additionally, similar to at least block 320 of FIG. 3, the updated characterization state-of-charge (SOC_{c}) can be converted, for example by the second state-of-charge system 224, to a user-defined state of charge (SOCᵤ) that corresponds to the operating voltage range of the second, and not the first, user-identified operating voltage range that was identified at block 718. Additionally, similar to block 322 discussed above with respect to FIG. 3, the user-defined state of charge (SOCᵤ) obtained at block 718 can then be displayed to the operator, such as, for example, via the display 226, at block 720. The method 700 can then be subsequently repeated, with the second user-identified operating voltage range becoming, with respect to at least the terminology utilized above with respect to block 702, the first user-identified operating voltage range.

While the disclosure has been illustrated and described in detail in the foregoing drawings and description, the same is to be considered as exemplary and not restrictive in character, it being understood that only illustrative embodiments thereof have been shown and described and that all changes and modifications that come within the spirit of the disclosure are desired to be protected.

1. A state-of-charge remapping system for determining a characterization state-of-charge and a user-defined state-of-charge for a rechargeable battery, the state-of-charge remapping system comprising:
at least one processor;
a memory coupled to the at least one processor, the memory including instructions that when executed by the at least one processor cause the at least one processor to:
receive an initial user-defined state-of-charge, the initial user-defined state-of-charge corresponding to a user-defined operating voltage range, the user-defined operating voltage range being within, and a narrower range than, a characterization operating voltage range that corresponds to the characterization state-of-charge;
convert the initial user-defined state-of-charge to an initial characterization state-of-charge using results of characterization testing obtained for the characterization operating voltage range, and without use of results of characterization testing based on the user-defined operating voltage range;
initialize, using the initial characterization state-of-charge, an equivalent circuit model;
generate, from operation of the equivalent circuit model, at least the updated characterization state-of-charge;
convert, using information derived from the results of the characterization testing obtained for the characterization operating voltage range, the updated characterization state-of-charge to the updated user-defined state-of-charge.

2. The state-of-charge remapping system of claim 1, wherein the at least one processor is further configured to:
output the user-defined state-of-charge obtained from the conversion of the characterization state-of-charge to an external interface.

3. The state-of-charge remapping system of claim 1, wherein the at least one processor is further configured to convert the characterization state-of-charge to the user-defined state-of-charge without use of results of characterization testing based on either the initial user-defined state-of-charge or the user-defined state-of-charge.

4. The state-of-charge remapping system of claim 1, wherein the at least one processor is further configured to initialize the equivalent circuit model by determining, using the initial characterization state-of-charge, at least a first characterization state-of-charge, the characterization state-of-charge being a function of at least the initial characterization state-of-charge for a given current input at a select time.

5. The state-of-charge remapping system of claim 4, wherein the at least one processor is further configured to receive a battery load profile comprising the given current input and the select time.

6. The state-of-charge remapping system of claim 1, wherein the at least one processor is configured to initialize the equivalent circuit model by identifying a value for each of one or more parameters of the equivalent circuit model, the value being at least a function of the initial characterization state-of-charge.

7. The state-of-charge remapping system of claim 1, wherein the at least one processor is configured to generate, via an operation of the equivalent circuit model, a simulated voltage, and determine, using the simulated voltage, a presence of either an overvoltage condition or an under-voltage condition of the rechargeable battery.

8. The state-of-charge remapping system of claim 1, wherein the characterization operating voltage range is an operating range is at least approximately a capacity of the rechargeable battery.

9. A state-of-charge remapping system for determining a characterization state-of-charge and a user-defined state-of-charge for a rechargeable battery using results of characterization testing obtained for a characterization operating voltage range that corresponds to the characterization state-of-charge, the state-of-charge remapping system comprising:
at least one processor;
a memory coupled to the at least one processor, the memory including instructions that when executed by the at least one processor cause the at least one processor to:
receive a first signal corresponding to a sensed battery voltage;
receive a second signal corresponding to a sensed battery load current;
leverage an equivalent circuit model to estimate, using at least the first and second signals, a characterization state-of-charge;
convert the characterization state-of-charge to the user-defined state-of-charge using the results of characterization testing obtained for the characterization operating voltage range, and without use of results of characterization testing based on the user-defined state-of-charge.

10. The state-of-charge remapping system of claim 9, wherein the at least one processor is further configured to:
output the user-defined state-of-charge obtained from the conversion of the characterization state-of-charge to an external interface.

11. The state-of-charge remapping system of claim 10, wherein the at least one processor is a processor of a battery management system.

12. The state-of-charge remapping system of claim 9, wherein the sensed battery voltage is a measured voltage.

13. The state-of-charge remapping system of claim 9, wherein the sensed battery load current is a measured current.

14. The state-of-charge remapping system of claim 9, wherein the value for each of one or more parameters of the equivalent circuit model is a function of at least the characterization state-of-charge.

15. The state-of-charge remapping system of claim 9, wherein the characterization operating voltage range is an operating range is at least approximately a total capacity of the rechargeable battery.

16. A method for online reconfiguration of a battery operating voltage range, the method comprising:
receiving a signal in response to a change in a state of health condition of a rechargeable battery, the rechargeable battery being operated at a first user-defined operating voltage range, the first user-defined operating voltage range being different than, and within, a characterization operating voltage range of the rechargeable battery;
adjusting, in response to receiving the signal, the first user-defined operating voltage range to a second user-defined operating voltage range, the second user-defined operating voltage range being different than the first user-defined operating voltage;
determining an initial user-defined state-of-charge corresponding to the second user-defined operating voltage range;
converting the initial user-defined state-of-charge to an initial characterization state-of-charge using characterization testing obtained for a characterization operating voltage range, the characterization operating voltage range being different than the second user-defined operating voltage range;
generating, using the initial characterization state-of-charge, a value for each of one or more parameters of an equivalent circuit model;
generating, via operation of the equivalent circuit model, an updated characterization state-of-charge; and
converting the updated characterization state-of-charge to an updated user-defined state-of-charge using results of characterization testing using an operating voltage range different than the second user-defined operating voltage range, and without use of results of characterization testing based on the second user-defined state-of-charge.

17. The method of claim 16, further including outputting the user-defined state-of-charge obtained from the conversion of the characterization state-of-charge to an external interface.

18. The method of claim 16, further including:
determining, using information provided by at least an aging estimator, the second user-defined operating voltage range; and
operating the rechargeable battery to avoid violating both an upper limit and a lower limit of the second user-defined operating voltage range.

19. The method of claim 16, further including:
determining, using information provided by at least an aging estimator, a plurality of operating voltage ranges;
receiving a user selection of a selected operating voltage range from the plurality of operating voltage ranges, the selected operating voltage range being the second user-defined operating voltage range; and
operating the rechargeable battery to avoid violating both an upper limit and a lower limit of the second user-defined operating voltage range.

20. The method of claim 16, wherein the state of health condition is an indication of aging of the rechargeable battery.
